(19) United States
(12) Patent Application Publication
(10) Pub. No.: US 2007/0296054 A1
(43) Pub. Date: Dec. 27, 2007

(54) Fuse with silicon nitride removed from fuse surface in cutting region

(76) Inventor: Sang Yeon Kim, Seongnam-city (KR)

Correspondence Address: FENWICK & WEST LLP, SILICON VALLEY CENTER, 801 CALIFORNIA STREET, MOUNTAIN VIEW, CA, 94041, US

(21) Appl. No.: 11/477,073

(22) Filed: Jun. 27, 2006

(51) Int. Cl. H01L 29/00

(52) U.S. Cl. 257/529; 257/E23.149

(57) ABSTRACT

A fuse is formed by a borderless contact process that removes the silicon nitride layer above the cutting region of the fuse. The fuse is formed on a semiconductor substrate, and comprises an insulation layer such as an oxide layer formed on the substrate, a fuse layer formed on the insulation layer, where the fuse layer includes at least a first region and a second region, and a silicon nitride layer formed only above the first region of the fuse layer. The first region of the fuse layer is where contact holes are formed for applying electrical stress to the fuse, and the second region of the fuse layer is where the fuse is cut in response to electrical stress applied to the fuse. Because the silicon nitride layer is removed above the second region of the fuse layer, the silicon nitride layer does not inhibit the cutting of the fuse in response to electrical stress applied to the fuse.

### BACKGROUND OF THE INVENTION

1. Field of the Invention

The present invention relates to a fuse in an integrated circuit and, more specifically, to a fuse in an integrated circuit formed by a borderless contact process with the silicon nitride layer removed from the fuse surface in the region where the fuse is cut in response to electrical stress.

2. Description of the Related Art

An integrated circuit (IC) often includes fuses for use in connecting or disconnecting certain electronic devices within the ICs. Fuses that can be cut by electrical stress or optical stress are increasingly being used in integrated circuits, because it is relatively easy to measure the changes in electrical characteristics in the fuses caused by variations in the IC fabrication process parameters after the fabrication process is complete and to compensate for the changes. Especially, fuses that can be cut by electrical stress are used in many IC applications because of the relative ease in cutting the fuses by electrical stress, compared to cutting fuses by optical stress applied using a laser beam.

Fuses in ICs typically have contact holes for use in applying electrical voltage to cut the fuses. As the ICs become more and more highly integrated, it is becoming increasingly difficult to accurately form the contact holes in ICs. FIGS. 1A and 1B illustrate a contact hole formed in an IC and its misalign margin in general. Note that FIGS. 1A and 1B are merely for illustrating the misalign margin of a contact hole in general and does not specifically illustrate a fuse. Referring to FIG. 1A, STIs (shallow trench isolations) 103 typically comprised of silicon oxide and an active layer 105 typically doped with n type or p type are formed on a semiconductor substrate 102. A contact hole 106 is formed on the active layer 105 in order to apply electrical voltage to the active layer 105, and a metal line 107 is formed on the contact hole 106. Interlayer dielectric (ILD) 104 is formed between the active layer 105 and the metal line 107 to electrically insulate the active layer 105 from the metal line 107.

The misalign margin 101 is the margin within which the contact hole 106 can be formed. As the ICs become more and more highly integrated, such misalign margin 101 becomes narrower. Referring to FIG. 1B, if the contact hole 106 is not formed within the misalign margin 101, the contact hole 106 may be formed partially over the STI 103, during which the silicon oxide forming the STI 103 is partially etched away (see circled region 108). As a result, electrical voltage applied to the metal line 107 through the contact hole 106 is not only applied to the active layer 105 but also applied to the substrate 102, resulting in a faulty IC.

FIG. 1C illustrates a conventional borderless contact process used in order to prevent the contact hole 107 from etching away the STI 103 even if the contact hole 107 is formed outside the misalign margin 101. As shown in FIG. 1C, in the borderless contact process, a silicon nitride (SiN) layer 109 is deposited on the active layer 105 after the gate electrodes (not shown) and the source/drain regions of MOS transistors (not shown) are formed but prior to depositing the ILD layer 104 as a contact etch stop layer. Thereafter, the ILD layer 104 is deposited, and the ILD layer 104 and the silicon nitride layer 109 are where the contact hole 107 is formed. Due to the etch selectivity difference between silicon oxide forming the ILD layer 104 and the silicon nitride layer 109, the contact hole 107 does not reach the substrate 102, as shown in FIG. 1C.

FIG. 2A is a plan view of a conventional fuse formed on a semiconductor substrate using a conventional borderless contact process, and FIG. 2B and FIG. 2C are cross-sectional views of the conventional fuse of FIG. 2A along lines A-A′ and B-B′, respectively, of the semiconductor substrate. Referring to FIG. 2A, the fuse includes the regions 240 where the contact holes 220 are formed and the cutting region 230 of the fuse where the fuse is cut in response to electrical stress applied to the fuse. Referring to FIGS. 2A and 2B, an insulation layer such as a silicon oxide layer 203 is formed on the semiconductor substrate 202, and the polysilicon fuse layer 210 is formed on the silicon oxide layer 203. Consistent with a borderless contact process, a silicon nitride layer 211 is formed on the fuse 210 to prevent the contact holes 220 from reaching the silicon substrate 202 when the contact holes 220 are formed. Note that the silicon nitride layer 211 is formed on the fuse layer 210 above the fuse cutting region 230 as well as above the region 240 where the contact holes 220 are formed.

A drawback of the conventional fuse of FIGS. 2A-2C is that the fuse layer 210 is sometimes cut incompletely even if electrical stress is applied through the contact holes 220. Such incomplete cutting of the fuse layer 210 is caused because the silicon nitride layer 211 inhibits the fusing when electrical stress is applied to the fuse layer 210.

Therefore, there is a need for a fuse that can be completely cut, yet still include a silicon nitride layer formed by a borderless contact process. There is also a need for a method for fabricating a fuse that can be completely cut, yet still include a silicon nitride layer formed by a borderless contact process.

### SUMMARY OF THE INVENTION

Embodiments of the present invention include a fuse formed by a borderless contact process that does not have a silicon nitride layer above the cutting region of the fuse, so that the silicon nitride layer does not inhibit the cutting of the fuse in response to electrical stress. In one embodiment, the fuse is formed on a semiconductor substrate, and the fuse comprises an insulation layer such as an oxide layer formed on the substrate, a fuse layer formed on the insulation layer, where the fuse layer includes at least a first region and a second region, and a silicon nitride layer formed only above the first region of the fuse layer. The first region of the fuse layer is where contact holes are formed for applying electrical stress to the fuse, and the second region of the fuse layer is where the fuse is cut in response to electrical stress applied to the fuse. The silicon nitride layer prevents the contact holes from reaching the substrate while the contact holes are formed in the first region of the fuse. On the other hand, because the silicon nitride layer is removed and does not exist above the second region of the fuse layer, the silicon nitride layer does not inhibit the cutting of the fuse.

In another embodiment, a method of fabricating a fuse on a semiconductor substrate is provided, where the fuse is fabricated by a borderless contact process but the silicon nitride layer is removed above the cutting region of the fuse. The method comprises forming an insulation layer such as an oxide layer on the substrate, forming a fuse layer on the insulation layer, where the fuse layer includes at least a first region and a second region, forming a silicon nitride layer above the first region and the second region of the fuse layer, and removing the silicon nitride layer formed above the second region of the fuse layer, for example, by way of etching the silicon nitride layer formed above the second region of the fuse layer by a photolithographic process. The method may further comprise forming interlayer dielectric on the silicon nitride layer in the first region of the fuse and on the fuse layer in the second region of the fuse, and forming contact holes for applying electrical stress to the fuse within the interlayer dielectric in the first region of the fuse layer. The silicon nitride layer prevents contact holes from reaching the substrate while the contact holes are formed in the first region of the fuse. On the other hand, the second region of the fuse layer is where the fuse is cut in response to electrical stress applied to the fuse. Because the silicon nitride layer is removed and does not exist above the second region of the fuse layer, the silicon nitride layer does not inhibit the cutting of the fuse.

The features and advantages described in the specification are not all inclusive and, in particular, many additional features and advantages will be apparent to one of ordinary skill in the art in view of the drawings, specification, and claims. Moreover, it should be noted that the language used in the specification has been principally selected for readability and instructional purposes, and may not have been selected to delineate or circumscribe the inventive subject matter.

### BRIEF DESCRIPTION OF THE DRAWINGS

The teachings of the embodiments of the present invention can be readily understood by considering the following detailed description in conjunction with the accompanying drawings.

FIGS. 1A and 1B illustrate a contact hole formed in an IC and its misalign margin.

FIG. 1C illustrates a conventional borderless contact process used in order to prevent the contact hole from etching away the STI even if the contact hole is formed outside the misalign margin.

FIG. 2A is a plan view of a conventional fuse formed on a semiconductor substrate using a conventional borderless contact process.

FIG. 2B and FIG. 2C are cross-sectional views of the conventional fuse of FIG. 2A along lines A-A′ and B-B′, respectively, of the semiconductor substrate.

FIG. 3A is a plan view of a fuse formed on a semiconductor substrate, according to one embodiment of the present invention.

FIG. 3B and FIG. 3C are cross-sectional views of the fuse of FIG. 3A according to one embodiment of the present invention, along lines A-A′ and B-B′, respectively, of the semiconductor substrate.

FIGS. 4A-4N are cross-sectional views of the fuse formed on a semiconductor substrate, illustrating a method of fabricating the fuse, according to one embodiment of the present invention.

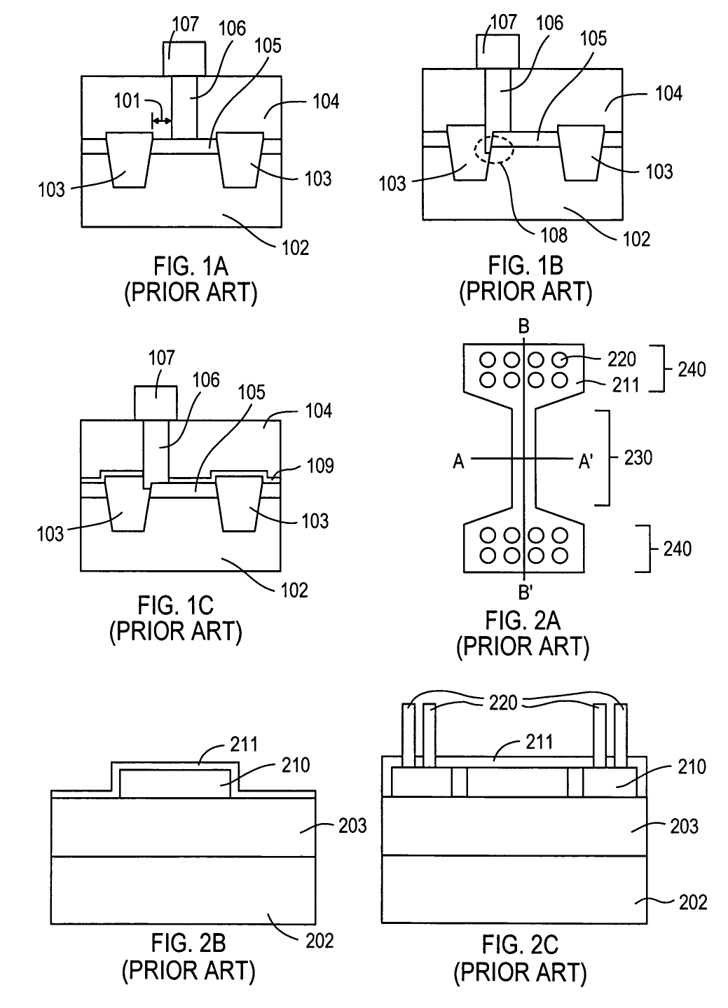

### DETAILED DESCRIPTION OF EMBODIMENTS

The Figures (FIG.) and the following description relate to preferred embodiments of the present invention by way of illustration only. It should be noted that from the following discussion, alternative embodiments of the structures and methods disclosed herein will be readily recognized as viable alternatives that may be employed without departing from the principles of the claimed invention.

Reference will now be made in detail to several embodiments of the present invention(s), examples of which are illustrated in the accompanying figures. It is noted that wherever practicable similar or like reference numbers may be used in the figures and may indicate similar or like functionality. The figures depict embodiments of the present invention for purposes of illustration only. One skilled in the art will readily recognize from the following description that alternative embodiments of the structures and methods illustrated herein may be employed without departing from the principles of the invention described herein.

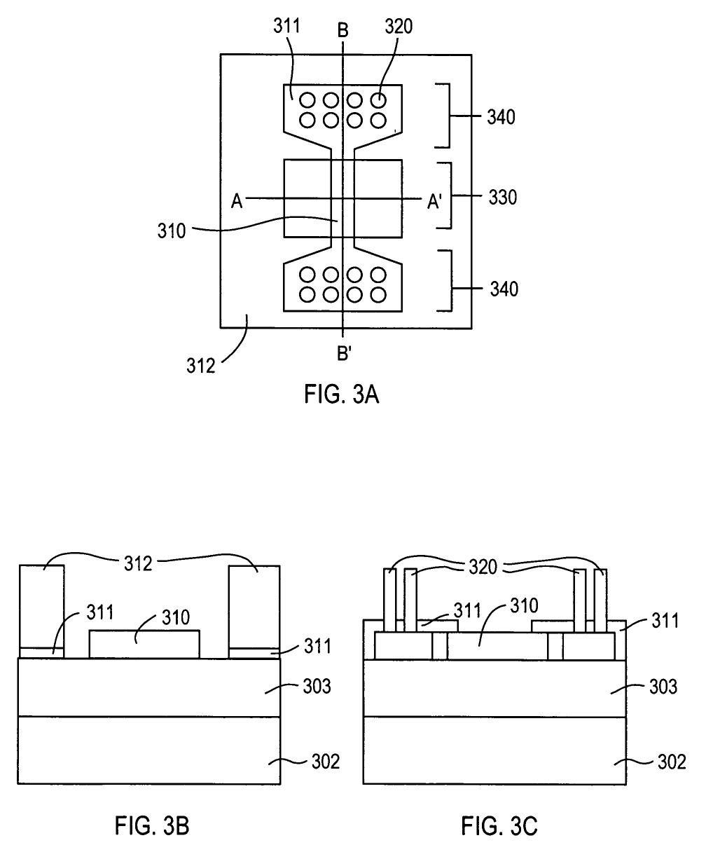

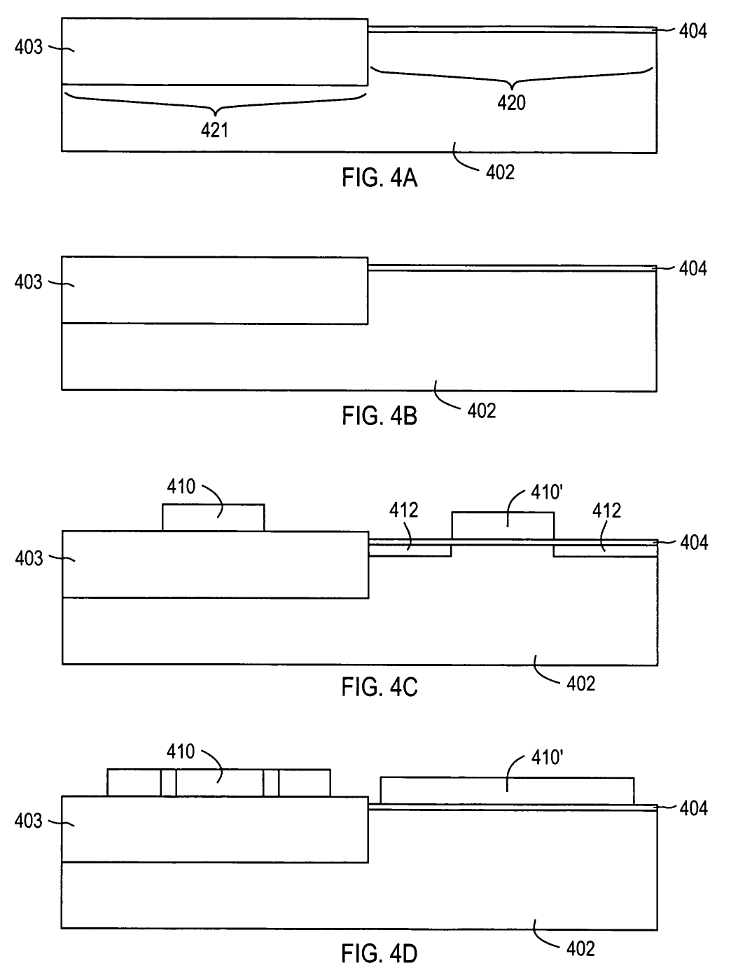

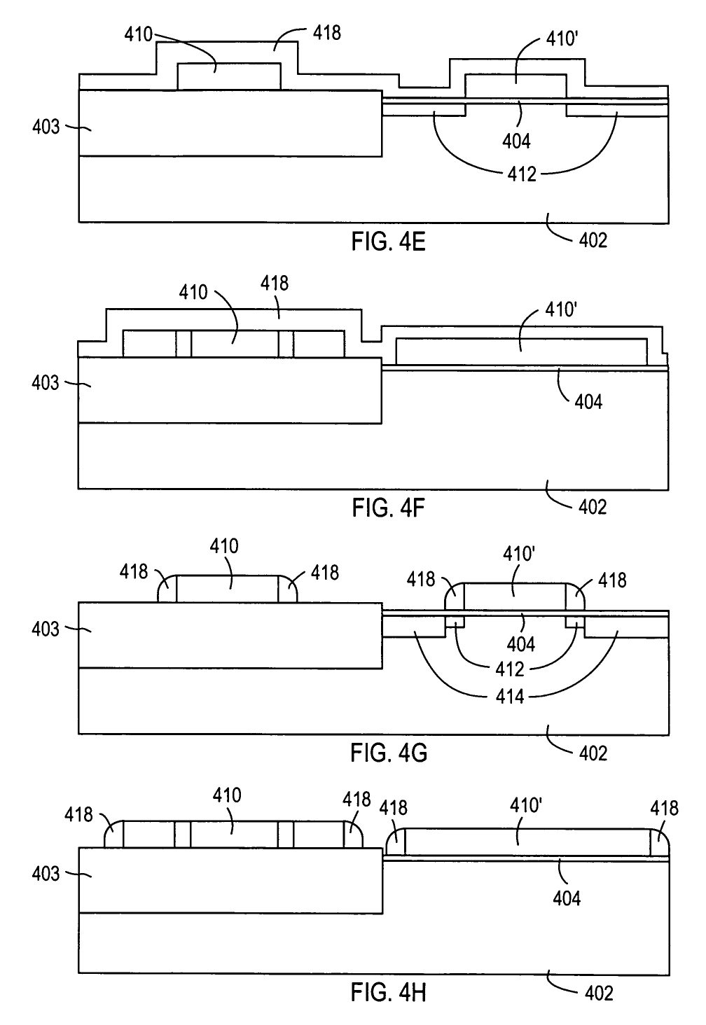

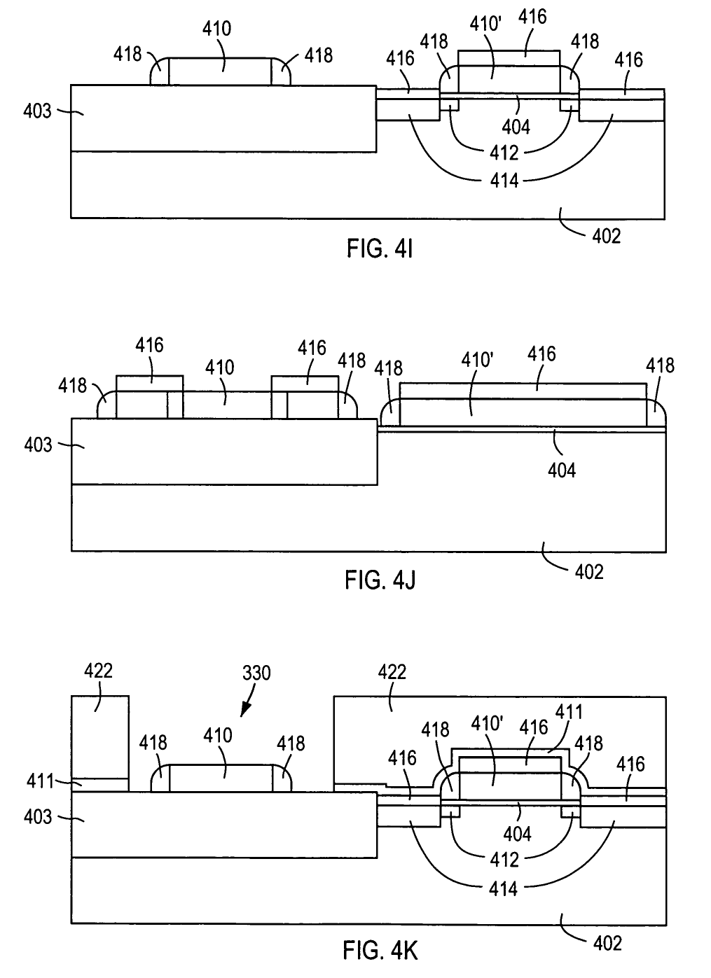

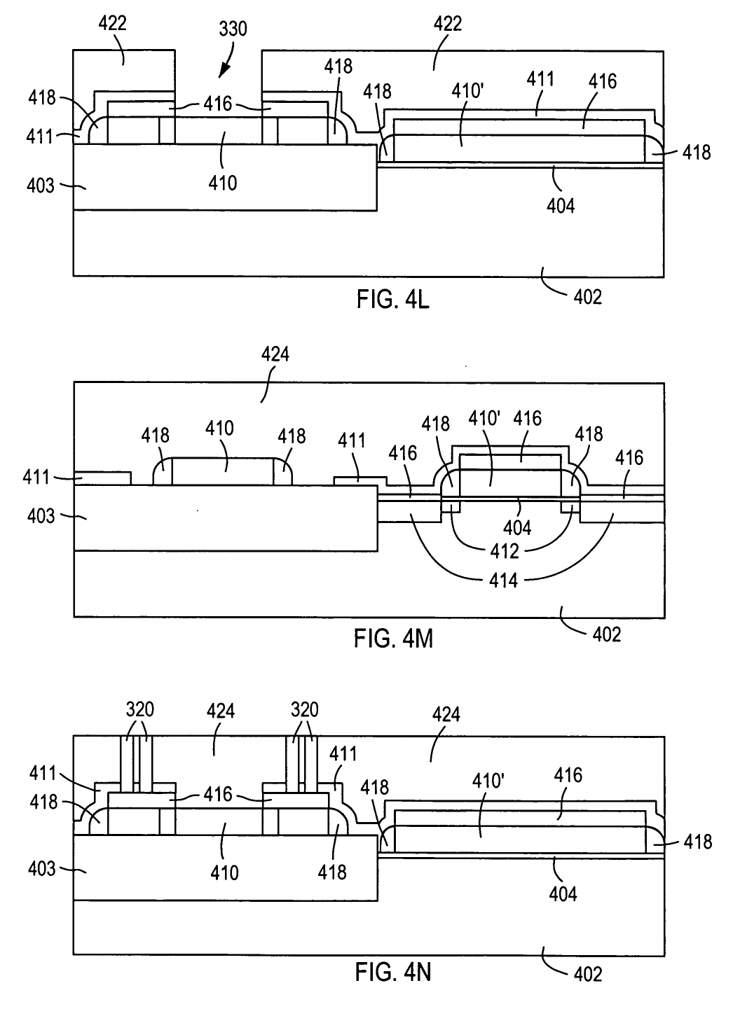

FIG. 3A is a plan view of a fuse formed on a semiconductor substrate, according to one embodiment of the present invention, and FIG. 3B and FIG. 3C are cross-sectional views of the fuse of FIG. 3A according to one embodiment of the present invention, along lines A-A′ and B-B′, respectively, of the semiconductor substrate. Note that the cross-sectional views of the fuse in FIGS. 3A and 3B are simplified views for illustration purposes only, and the actual fuse will include additional layers, as will be illustrated below with reference to FIGS. 4A-4N.

Referring to FIG. 3A, the fuse includes the regions 340 where the contact holes 320 are formed and the cutting region 330 of the fuse. Referring to FIGS. 3B and 3C, an insulation layer such as a silicon oxide layer 303 is formed on the semiconductor substrate 302, and the polysilicon fuse layer 310 is formed on the silicon oxide layer 303. Also consistent with a borderless contact process, a silicon nitride layer 311 is formed on the fuse layer 310 to prevent the contact holes 320 from reaching the silicon substrate 302 when the contact holes 320 are formed.

However, according to the present invention, the silicon nitride layer 311 is removed in the cutting region 330 of the fuse by way of a photolithographic etching process using the photoresistor 312. Therefore, the fuse layer 310 is exposed without the silicon nitride layer above the fuse layer 310 in the cutting region 330 of the fuse. Thus, the fuse layer 310 can be completely cut when electrical stress is applied through the contact holes 320, because there is no silicon nitride layer in the cutting region 330 of the fuse that would otherwise inhibit the cutting of the fuse layer 310 when electrical stress is applied. Note, however, that the silicon nitride layer 311 still remains deposited on the fuse layer 310 in the contact hole regions 340 of the fuse where the contact holes 320 are formed, as shown in FIGS. 3A and 3C. Therefore, the contact holes 320 are still prevented from reaching the substrate layer 302 when the contact holes 320 are formed.

FIGS. 4A-4N are cross-sectional views of the fuse formed on a semiconductor substrate, illustrating a method of fabricating the fuse, according to one embodiment of the present invention. Note that FIGS. 4A-4N illustrate the fabrication process of the fuse together with the fabrication of a MOSFET (metal-oxide semiconductor field effect transistor) formed adjacent to the fuse, as would be typical in an IC. Specifically, FIGS. 4A, 4C, 4E, 4G, 4I, 4K, and 4M are cross-section views of the fuse formed on the semiconductor substrate, together with an adjacent MOSFET (not shown in FIG. 3A), along line A-A′ of the fuse shown in FIG. 3A, and FIGS. 4B, 4D, 4F, 4H, 4J, 4L, and 4N are cross-section views of the fuse formed on the semiconductor substrate, together with another adjacent MOSFET (not shown in FIG. 3A), along line B-B′ of the fuse shown in FIG. 3A. Note that FIGS. 4A, 4C, 4E, 4G, 41, 4K, and 4M correspond to the same processing stage as FIGS. 4B, 4D, 4F, 4H, 4J, 4L, and 4N, respectively. Also note that certain process steps that are not critical to illustrating the present invention are omitted from FIGS. 4A-4N.

Referring to FIGS. 4A and 4B, an active region 420 and an insulation region such as a field oxide region 421 are formed on the semiconductor substrate 402. In one embodiment, the semiconductor substrate 402 is a silicon substrate. The field oxide 403 is formed on the substrate 402 in the fixed oxide region 421, and a gate oxide layer 404 is formed on the substrate 402 in the active region 420. In addition, a process step for adjusting the threshold voltage (Vth) of the MOSFET is performed but is omitted in FIGS. 4A and 4B.

Referring to FIGS. 4C and 4D, a polysilicon layer is deposited on the field oxide layer 403 and the gate oxide layer 404 and is subsequently patterned using an etching process to form the polysilicon fuse 410 and the polysilicon gate electrode 410′ of the MOSFET. Thereafter, the source/drain contacts 412 are formed using an LDD (lightly doped drain) ion implantation process. Then, referring to FIGS. 4E and 4F, a spacer insulation layer 418 typically comprised of silicon oxide is formed to cover the fuse 410, the gate electrode 410′, the exposed parts of the field oxide layer 403, and the exposed parts of the gate oxide layer 404.

Referring to FIGS. 4G and 4H, the spacer insulation layer 418 is etched back, so that the spacer insulation layer 418 remains only adjacent to the sidewalls of the fuse layer 410 and the gate electrode 410′, and the remaining parts of the field oxide 403 and the gate oxide layer 404 are exposed. Thereafter, the N+ regions 414 of the source/drain contacts 412 are formed using LDD ion implantation.

Referring to FIGS. 4I and 4J, a salicide (self-aligned silicide) layer 416 is formed from cobalt over the active region 420, exposed to thermal heating, and wet etched, so that the salicide layer 416 remains only above the gate electrode 410′ and the source/drain contacts 412, 414. The salicide layer 416, which has low impedance, is not formed on the cutting regions of the fuse 410, by way of a salicide blocking process using silicon oxide preventing the salicide from forming from cobalt.

Referring to FIGS. 4K and 4L, the silicon nitride layer 411 (used in the borderless contact process) is formed over the field oxide region 421 and the active region 420, and then etched away by way of photolithography using the patterned photoresistor 422, so that the silicon nitride layer 411 is removed in the cutting region 330 of the fuse 410 and the fuse 410 is exposed in the cutting region 330.

Referring to FIGS. 4M and 4N, the photoresistor 422 is removed, interlayer dielectric (ILD) 424 is formed over the field oxide region 421 and the active region 420, and the ILD layer 424 goes through a CMP (chemical mechanical planarization) process. Thereafter, contact holes 320 are formed in the contact hole regions 340 (see FIG. 3A) of the fuse 410. The remaining process steps are typical CMOS (Complementary MOS) process steps that are not critical to the illustration of the present invention, and thus are omitted herein.

Because the fuse 410 is exposed without the silicon nitride layer 411 above the fuse layer 310 in the cutting region 330 of the fuse, the fuse layer 410 can be completely cut when electrical stress is applied through the contact holes 320, because there is no silicon nitride layer in the cutting region 330 of the fuse 410 that would otherwise inhibit the cutting of the fuse 410 when electrical stress is applied. In addition, the silicon nitride layer 411 still remains deposited on the fuse 410 in the contact hole regions 340 of the fuse where the contact holes 320 are formed. Therefore, the contact holes 320 are still prevented from reaching the substrate layer 402 when the contact holes 320 are formed.

Upon reading this disclosure, those of ordinary skill in the art will appreciate still additional alternative structural and functional designs for a polysilicon fuse fabricated using a borderless contact process. Thus, while particular embodiments and applications of the present invention have been illustrated and described, it is to be understood that the invention is not limited to the precise construction and components disclosed herein. Various modifications, changes and variations which will be apparent to those skilled in the art may be made in the arrangement, operation and details of the method and apparatus of the present invention disclosed herein without departing from the spirit and scope of the invention as defined in the appended claims.

What is claimed is:

1. A fuse formed on a semiconductor substrate, the fuse comprising:
an insulation layer formed on the substrate;
a fuse layer formed on the insulation layer, the fuse layer including at least a first region and a second region; and
a silicon nitride layer formed only above the first region of the fuse layer.

2. The fuse of claim 1, wherein the first region of the fuse layer is where contact holes are formed for applying electrical stress to the fuse.

3. The fuse of claim 2, wherein the silicon nitride layer prevents the contact holes from reaching the substrate while the contact holes are formed in the first region of the fuse.

4. The fuse of claim 1, wherein the second region of the fuse layer is where the fuse is cut in response to electrical stress applied to the fuse.

5. The fuse of claim 1, wherein the semiconductor substrate is comprised of silicon and the insulation layer is comprised of silicon oxide.

6. The fuse of claim 1, wherein the semiconductor substrate is comprised of silicon and the fuse layer is comprised of polysilicon.

7. The fuse of claim 1, wherein interlayer dielectric is formed on the silicon nitride layer in the first region of the fuse and the interlayer dielectric is formed on the fuse layer in the second region of the fuse.

8. A method of fabricating a fuse on a semiconductor substrate, the method comprising:
forming an insulation layer on the substrate;
forming a fuse layer on the insulation layer, the fuse layer including at least a first region and a second region;
forming a silicon nitride layer above the first region and the second region of the fuse layer; and
removing the silicon nitride layer formed above the second region of the fuse layer.

9. The method of claim 8, further comprising forming interlayer dielectric on the silicon nitride layer in the first region of the fuse and on the fuse layer in the second region of the fuse.

10. The method of claim 9, further comprising forming contact holes for applying electrical stress to the fuse within the interlayer dielectric in the first region of the fuse layer.

11. The method of claim 10, wherein the silicon nitride layer prevents the contact holes from reaching the substrate while the contact holes are formed in the first region of the fuse.

12. The method of claim 8, wherein the second region of the fuse layer is where the fuse is cut in response to electrical stress applied to the fuse.

13. The method of claim 8, wherein the semiconductor substrate is comprised of silicon and the insulation layer is comprised of silicon oxide.

14. The method of claim 8, wherein the semiconductor substrate is comprised of silicon and the fuse layer is comprised of polysilicon.

15. The method of claim 8, wherein removing the silicon nitride layer comprises etching the silicon nitride layer formed above the second region of the fuse layer by a photolithographic process.

16. An integrated circuit formed on a semiconductor substrate, the integrated circuit comprising:
a fuse formed on the semiconductor substrate, the fuse comprising:
an insulation layer formed on the substrate;
a fuse layer formed on the insulation layer, the fuse layer including at least a first region and a second region; and
a silicon nitride layer formed only above the first region of the fuse layer; and
at least a transistor formed on the substrate.

17. The integrated circuit of claim 16, wherein the first region of the fuse layer is where contact holes are formed for applying electrical stress to the fuse.

18. The integrated circuit of claim 17, wherein the silicon nitride layer prevents the contact holes from reaching the substrate while the contact holes are formed in the first region of the fuse.

19. The integrated circuit of claim 16, wherein the second region of the fuse layer is where the fuse is cut in response to electrical stress applied to the fuse.

20. The integrated circuit of claim 16, wherein interlayer dielectric is formed on the silicon nitride layer in the first region of the fuse and the interlayer dielectric is formed on the fuse layer in the second region of the fuse.

21. A method of fabricating an integrated circuit including a fuse and at least a transistor on a semiconductor substrate, the method comprising:
forming a field oxide layer for the fuse and a gate oxide layer for the transistor on the substrate;
forming a fuse layer on the field oxide layer and a gate electrode for the transistor on the gate oxide layer, the fuse layer including at least a first region and a second region;
forming a source region and drain region for the transistor in the substrate;
forming a silicon nitride layer above the first region and the second region of the fuse layer and above the source region, the drain region, and the gate electrode of the transistor; and
removing the silicon nitride layer formed above the second region of the fuse layer.

22. The method of claim 21, further comprising forming interlayer dielectric on the silicon nitride layer in the first region of the fuse and on the fuse layer in the second region of the fuse.

23. The method of claim 22, further comprising forming contact holes for applying electrical stress to the fuse within the interlayer dielectric in the first region of the fuse layer.

24. The method of claim 23, wherein the silicon nitride layer prevents the contact holes from reaching the substrate while the contact holes are formed in the first region of the fuse.

25. The method of claim 21, wherein the second region of the fuse layer is where the fuse is cut in response to electrical stress applied to the fuse.

26. The method of claim 21, wherein removing the silicon nitride layer comprises etching the silicon nitride layer formed above the second region of the fuse layer by a photolithographic process.
